(19) United States
(12) Patent Application Publication
(10) Pub. No.: US 2025/0386866 A1
(43) Pub. Date: Dec. 25, 2025

(54) AEROSOL PROVISION DEVICE

(71) Applicant: Nicoventures Trading Limited, London (GB)

(72) Inventors: Craig GOODING, London (GB); Conor MCGRATH, London (GB); Jorge GOMEZ, London (GB); Matthew HOLDEN, London (GB); Shuihui LV, Longgang District Shenzhen, Guangdong (CN); Pan HUIPING, Longgang District Shenzhen, Guangdong (CN); Liu LIANG, Longgang District Shenzhen, Guangdong (CN)

(21) Appl. No.: 18/879,665

(22) PCT Filed: Jun. 28, 2023
(86) PCT No.: PCT/EP2023/067717

§ 371 Date: Dec. 27, 2024

(30) Foreign Application Priority Data
Jun. 30, 2022 (CN) 2022107608972
Jul. 20, 2022 (GB) 2210591.0

(51) Int. Cl. A24F 40/465; A24F 40/20; A24F 40/50; H05K 9/00

(52) U.S. Cl. CPC A24F 40/465; A24F 40/20; A24F 40/50; H05K 9/0067

(57) ABSTRACT

An aerosol provision device for generating an aerosol from aerosol-generating material includes a heating assembly and an electrically conductive housing part arranged to at least partially receive the heating assembly. The device includes an electronics module and a contact member. The at least one contact member is in electrical contact between the housing part and the electronics module to provide an electrostatic discharge pathway.

### RELATED APPLICATIONS

The present application is a National Phase entry of PCT Application No. PCT/EP2023/067717 filed Jun. 28, 2023, which claims priority to CN application Ser. No. 20/221,07608972 filed Jun. 30, 2022 and GB Application No. 2210591.0 filed Jul. 20, 2022, each of which is hereby incorporated by reference in their entirety.

### TECHNICAL FIELD

The present invention relates to an aerosol provision device. The present invention also relates to an aerosol provision system comprising an aerosol provision device and an article comprising aerosol generating material.

### BACKGROUND

Smoking articles such as cigarettes, cigars and the like burn tobacco during use to create tobacco smoke. Attempts have been made to provide alternatives to these articles that burn tobacco by creating products that release compounds without burning. Examples of such products are heating devices which release compounds by heating, but not burning, the material. The material may be for example tobacco or other non-tobacco products, which may or may not contain nicotine.

### SUMMARY

In accordance with some embodiments described herein, there is provided an aerosol provision device comprising a heating assembly, an electrically conductive housing part arranged to at least partially receive the heating assembly, an electronics module, and a contact member, wherein the at least one contact member is in electrical contact between the housing part and the electronics module to provide an electrostatic discharge pathway.

The contact member may extend from the electronics module. The contact member may be fixedly mounted on the electronics module. The contact member may be a resiliently deformable member.

A contact surface of the contact member may be biased away from the electronics module.

The contact member may be a spring element. The contact member may comprise a sprung pin.

The electronics module may comprise a printed circuit board assembly (PCBA).

The contact member may protrude from the PCBA. The contact member may be biased against the housing part. The housing part may comprise a connecting arrangement, and the contact member may be in contact with the connecting arrangement.

The device may comprise a chassis. The electronics module may be between the chassis and the heating assembly. The electronics module may be mounted on the chassis.

The contact member may be one of a plurality of contact members. The at least one contact member may be electrically connected to a ground point in the device. The ground point may comprise a ground component. The ground component is at zero volts.

In use, electrostatic discharge is directed from the housing to the ground point by the at least one contact point.

The at least one contact member may be electrically isolated from other electrical elements of the electronics module.

The electrically conductive housing part may surround the heating assembly. The electrically conductive housing part may comprise aluminum.

In accordance with some embodiments described herein, there is provided an aerosol provision system comprising the aerosol provision device described above and an article comprising aerosol-generating material.

In accordance with some embodiments described herein, there is provided a method of assembling an aerosol provision device for generating an aerosol from aerosol-generating material, comprising providing an electronics module with an electrostatic discharge contact member, bringing electrically conductive housing part together with the electronics module so that the electrostatic discharge contact member is brought into contact with the electrically conductive housing part and provides an electrostatic discharge pathway between the housing part and electronics module.

### BRIEF DESCRIPTION OF THE DRAWINGS

Embodiments of the invention will now be described, by way of example only, with reference to accompanying drawings, in which:

FIG. 1 shows a perspective view of an aerosol provision device with a housing shown in partial cutaway;

FIGS. 2a and 2b show a perspective view of the aerosol provision device of FIG. 1 without the housing;

FIGS. 3a and 3b show a perspective view of a battery assembly and electronics module of the aerosol provision device of FIG. 1;

FIG. 4 shows a perspective view of the battery assembly and PCBA of the aerosol provision device of FIG. 1;

FIG. 5 shows a perspective side view of a contact member of the aerosol provision device of FIG. 1; and

FIG. 6 shows a perspective section top view the aerosol provision device of FIG. 1.

### DETAILED DESCRIPTION

As used herein, the term “aerosol-generating material” is a material that is capable of generating aerosol, for example when heated, irradiated or energized in any other way. Aerosol-generating material may, for example, be in the form of a solid, liquid or gel which may or may not contain an active substance and/or flavorants. Aerosol-generating material may include any plant based material, such as tobacco-containing material and may, for example, include one or more of tobacco, tobacco derivatives, expanded tobacco, reconstituted tobacco or tobacco substitutes. Aerosol-generating material also may include other, non-tobacco, products, which, depending on the product, may or may not contain nicotine. Aerosol-generating material may for example be in the form of a solid, a liquid, a gel, a wax or the like. Aerosol-generating material may for example also be a combination or a blend of materials. Aerosol-generating material may also be known as “smokable material”.

The aerosol-generating material may comprise a binder and an aerosol former. Optionally, an active and/or filler may also be present. Optionally, a solvent, such as water, is also present and one or more other components of the aerosol-generating material may or may not be soluble in the solvent. In some embodiments, the aerosol-generating material is substantially free from botanical material. In some embodiments, the aerosol-generating material is substantially tobacco free.

The aerosol-generating material may comprise or be an “amorphous solid”. The amorphous solid may be a “monolithic solid”. In some embodiments, the amorphous solid may be a dried gel. The amorphous solid is a solid material that may retain some fluid, such as liquid, within it. In some embodiments, the aerosol-generating material may, for example, comprise from about 50 wt %, 60 wt % or 70 wt % of amorphous solid, to about 90 wt %, 95 wt % or 100 wt % of amorphous solid.

The aerosol-generating material may comprise an aerosol-generating film. The aerosol-generating film may comprise or be a sheet, which may optionally be shredded to form a shredded sheet. The aerosol-generating sheet or shredded sheet may be substantially tobacco free.

According to the present disclosure, a “non-combustible” aerosol provision system is one where a constituent aerosol-generating material of the aerosol provision system (or component thereof) is not combusted or burned in order to facilitate delivery of at least one substance to a user.

In some embodiments, the delivery system is a non-combustible aerosol provision system, such as a powered non-combustible aerosol provision system.

In some embodiments, the non-combustible aerosol provision system is an electronic cigarette, also known as a vaping device or electronic nicotine delivery system (END), although it is noted that the presence of nicotine in the aerosol-generating material is not a requirement.

In some embodiments, the non-combustible aerosol provision system is an aerosol-generating material heating system, also known as a heat-not-burn system. An example of such a system is a tobacco heating system.

In some embodiments, the non-combustible aerosol provision system is a hybrid system to generate aerosol using a combination of aerosol-generating materials, one or a plurality of which may be heated. Each of the aerosol-generating materials may be, for example, in the form of a solid, liquid or gel and may or may not contain nicotine. In some embodiments, the hybrid system comprises a liquid or gel aerosol-generating material and a solid aerosol-generating material. The solid aerosol-generating material may comprise, for example, tobacco or a non-tobacco product.

Typically, the non-combustible aerosol provision system may comprise a non-combustible aerosol provision device and a consumable for use with the non-combustible aerosol provision device.

In some embodiments, the disclosure relates to consumables comprising aerosol-generating material and configured to be used with non-combustible aerosol provision devices. These consumables are sometimes referred to as articles throughout the disclosure.

In some embodiments, the non-combustible aerosol provision system, such as a non-combustible aerosol provision device thereof, may comprise a power source and a controller. The power source may, for example, be an electric power source or an exothermic power source. In some embodiments, the exothermic power source comprises a carbon substrate which may be energized so as to distribute power in the form of heat to an aerosol-generating material or to a heat transfer material in proximity to the exothermic power source.

In some embodiments, the non-combustible aerosol provision system may comprise an area for receiving the consumable, an aerosol generator, an aerosol generation area, a housing, a mouthpiece, a filter and/or an aerosol-modifying agent.

In some embodiments, the consumable for use with the non-combustible aerosol provision device may comprise aerosol-generating material, an aerosol-generating material storage area, an aerosol-generating material transfer component, an aerosol generator, an aerosol generation area, a housing, a wrapper, a filter, a mouthpiece, and/or an aerosol-modifying agent.

An aerosol generating device can receive an article comprising aerosol generating material for heating. An “article” in this context is a component that includes or contains in use the aerosol generating material, which is heated to volatilize the aerosol generating material, and optionally other components in use. A user may insert the article into the aerosol generating device before it is heated to produce an aerosol, which the user subsequently inhales. The article may be, for example, of a predetermined or specific size that is configured to be placed within a heating chamber of the device which is sized to receive the article.

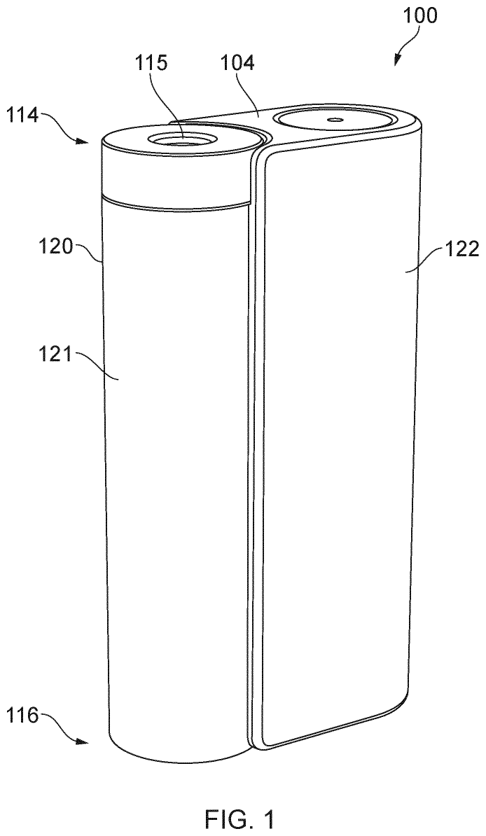

FIG. 1 shows an aerosol provision device for generating aerosol from an aerosol generating material. The device 100 may be used to heat a replaceable article (not shown) comprising the aerosol generating material, to generate aerosol or other inhalable medium which is inhaled by a user of the device 100.

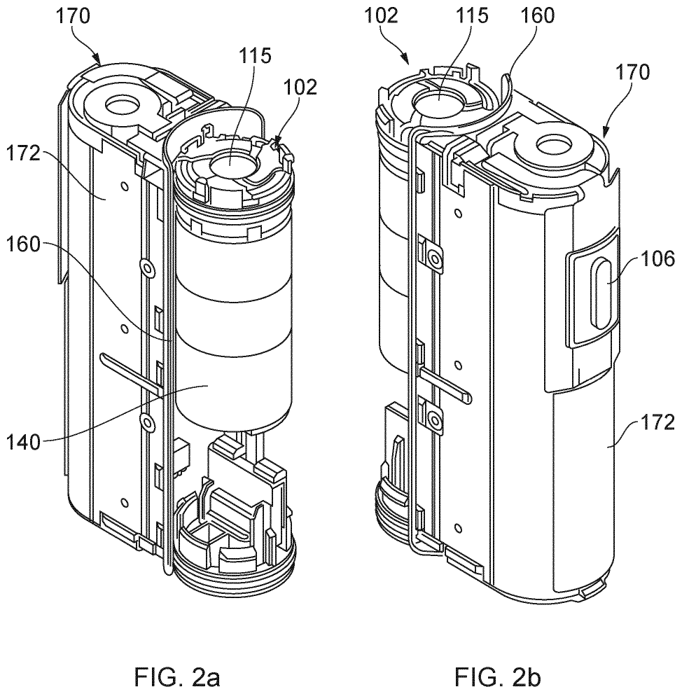

The device 100 comprises a body 104. The body 104 comprises a housing 120. The housing 120 surrounds and houses various components of the device 100. An article aperture 115 is formed in one end of the body 104, through which the article may be inserted for heating by an aerosol generator 102 (refer to FIG. 2). In use, the article may be fully or partially inserted into the aerosol generator 102 where it may be heated by one or more components of the aerosol generator 102. The aerosol generator 102 comprises a heating assembly 140. The article and the device 100 together form an aerosol provision system (not shown).

The housing 120 comprises a first housing, acting as a first housing part 121 and a second housing, acting as a second housing part 122. The first housing part is attached to the second housing part 122. The first and second housing parts 121, 122 together define a shell of the body 104. It will be understood that the number of housing parts may vary.

The device 100 may also include a user-operable control element 106 (FIG. 2), such as a button or switch, which operates the device 100 when pressed. For example, a user may turn on the device by operating the switch.

The body 104 has end surfaces of the device 100. The end of the device 100 closest to the article aperture 115 may be known as the proximal end (or mouth end) 114 of the device 100 because, in use, it is closest to the mouth of the user. In use, a user inserts an article into the aperture 115, operates the aerosol generator 102 to begin heating the aerosol generating material, and draws on the aerosol generated in the device 100. This causes the aerosol to flow through the device 100 along a flow path towards the proximal end 114 of the device 100.

The other end of the device furthest away from the aperture 115 may be known as the distal end 116 of the device 100 because, in use, it is the end furthest away from the mouth of the user. As a user draws on the aerosol generated in the device, the aerosol flows in a direction towards the proximal end 114 of the device 100. The terms proximal and distal as applied to features of the device 100 will be described by reference to the relative positioning of such features with respect to each other in a proximal-distal direction along the longitudinal axis 112.

The first housing part 121 may be a one-piece component. The second housing part 122 may be a one-piece component. As used herein, one-piece component refers to a component of the device 100 which is not separable into two or more components following assembly of the device 100. Integrally formed relates to two or more features that are formed into a one-piece component during a manufacturing stage of the component.

The first housing part 121 and the second housing part 122 are fixedly mounted. The first housing part 121 is tubular. The first housing part 121 is open along one side. The second housing part 122 is open along one side. The second housing part 122 is tubular. The first housing part 121 is at least partially received by the second housing part 122. It will be understood that the configurations of the first and second housing parts 121, 122 may differ. The first housing part 121 houses the aerosol generator 102. The second housing part 122 houses an electronics assembly 170. The body 104 comprises a chassis 160. The first housing part 121 is mounted to the chassis. The second housing part 122 is mounted to the chassis 160. The chassis 160 is received in the second housing part 122. The first and second housing parts 121, 122 enclose the chassis 160.

The heating assembly 140 may comprise an induction-type heating system, including a magnetic field generator comprising an inductor coil assembly. The heating assembly 140 comprises a heating element. The heating element is also known as a susceptor.

A susceptor is a material that is heatable by penetration with a varying magnetic field, such as an alternating magnetic field. The susceptor may be an electrically-conductive material, so that penetration thereof with a varying magnetic field causes induction heating of the heating material. The heating material may be magnetic material, so that penetration thereof with a varying magnetic field causes magnetic hysteresis heating of the heating material. The susceptor may be both electrically-conductive and magnetic, so that the susceptor is heatable by both heating mechanisms. The device that is configured to generate the varying magnetic field is referred to as a magnetic field generator, herein.

The heating assembly 140, forming part of the aerosol generator 102, is an inductive heating assembly and comprises various components to heat the aerosol generating material of the article via an inductive heating process. Induction heating is a process of heating an electrically conducting object (such as a susceptor) by electromagnetic induction. An induction heating assembly may comprise an inductive element, for example, one or more inductor coils, and a device for passing a varying electric current, such as an alternating electric current, through the inductive element. The varying electric current in the inductive element produces a varying magnetic field. The varying magnetic field penetrates a susceptor suitably positioned with respect to the inductive element, and generates eddy currents inside the susceptor. The susceptor has electrical resistance to the eddy currents, and hence the flow of the eddy currents against this resistance causes the susceptor to be heated by Joule heating. In cases where the susceptor comprises ferromagnetic material such as iron, nickel or cobalt, heat may also be generated by magnetic hysteresis losses in the susceptor, i.e. by the varying orientation of magnetic dipoles in the magnetic material as a result of their alignment with the varying magnetic field. In inductive heating, as compared to heating by conduction for example, heat is generated inside the susceptor, allowing for rapid heating. Further, there need not be any physical contact between the inductive heater and the susceptor, allowing for enhanced freedom in construction and application.

The heating element may be hollow and therefore define at least part of a receptacle within which aerosol generating material is received. For example, the article can be inserted into the heating element. The heating element is tubular, with a circular cross section. The heating element has a generally constant diameter along its axial length. In embodiments, the heating element protrudes in the receptacle. Other arrangements are anticipated.

The heating element is formed from an electrically conducting material suitable for heating by electromagnetic induction. The susceptor in the present example is formed from a carbon steel. It will be understood that other suitable materials may be used, for example a ferromagnetic material such as iron, nickel or cobalt. The heating element may be an elongate member protruding in the heating zone defined by the receptacle.

In other embodiments, the feature acting as the heating element may not be limited to being inductively heated. The feature, acting as a heating element, may therefore be heatable by electrical resistance. The aerosol generator 102 may therefore comprise electrical contacts for electrical connection with the apparatus for electrically activating the heating element by passing a flow of electrical energy through the heating element.

The electronics assembly 170 is in the body 104. The electronics assembly 170 is housed within the second housing part 122. The electronics assembly 170 comprises a power source 174. The power source 174 may be, for example, a battery, such as a rechargeable battery or a non-rechargeable battery. Examples of suitable batteries include, for example, a lithium battery (such as a lithium-ion battery), a nickel battery (such as a nickel-cadmium battery), and an alkaline battery. The battery 174 is electrically coupled to the heating assembly 140 to supply electrical power when required and under control of a controller to heat the aerosol generating material.

The electronics assembly 170 comprises an electronics module 150. The electronics module 150 comprises a printed circuit board assembly (PCBA). The PCBA may comprise, for example, a printed circuit board (PCB) that supports at least one controller, such as a processor, and memory. The PCB may also comprise one or more electrical tracks to electrically connect together various electronic components. The battery terminals may be electrically connected to the PCB so that power can be distributed throughout the device 100.

The aerosol generator 102 including the heating assembly 140 and the first housing part 121 define a first sub-assembly.

The chassis 160 and the electronics module 150 define a second sub-assembly.

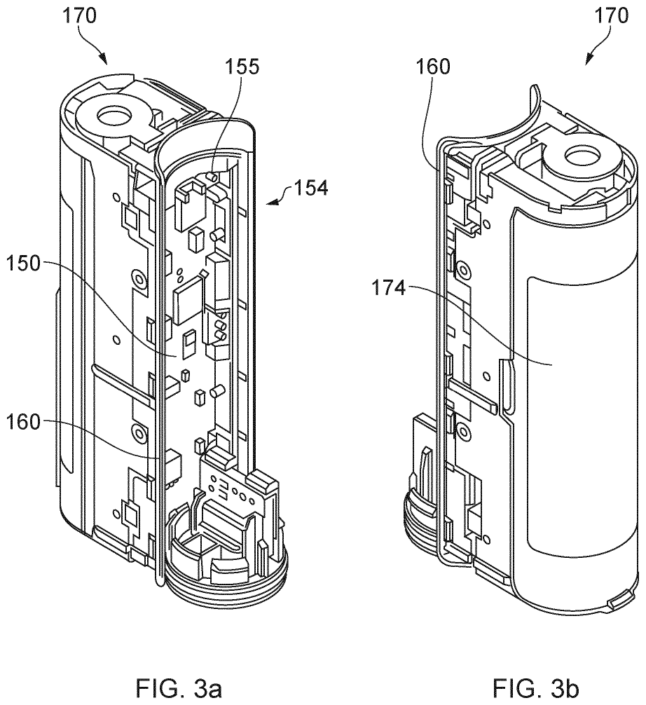

FIGS. 2a and 2b show a perspective view of the device 100 with the first and second housing parts 121, 122 omitted, to show the aerosol generator 104 and the electronics assembly 170. FIGS. 3a and 3b show a perspective view of the chassis and electronics assembly 170. The heating assembly 140 defines a longitudinal axis and the electronics assembly 170 defines a longitudinal axis, the axes being parallel to one another. The heating assembly 140 defines a heating chamber (not shown). The article is received in the heating chamber to be heated by the heating assembly 140. The heating assembly 140 is inserted axially into the first housing part 121.

The electronics assembly 170 comprises a thermal distribution assembly 172. The thermal distribution assembly 172 surrounds the battery 174. The thermal distribution assembly 172 includes a heat distribution panel. The heat distribution panel comprises a sheet of high thermal conductive material, for example a graphite sheet. The control element 106 is mounted externally to the thermal distribution assembly 172. The second housing part 122 may comprise a cutaway, or resiliently deformable portion to allow the user to activate the control element 106.

The chassis 160 acts as a battery carrier. The battery 174 is mounted on the chassis 160. The battery 174 extends on one side of the chassis 160. The electronics module 150 is mounted on another side of the chassis 160. The electronics assembly 170 comprises the chassis 160. The chassis 160 is adjacent to the aerosol generator 102. The chassis 160 receives a portion of the first housing part 121. The first housing part 121 is attached to the chassis 160. The second housing part 122 surrounds the electronics assembly 170, and surrounds an external portion of the chassis 160.

The PCBA 150 is mounted on the chassis 160. The chassis 160 locates and supports the PCBA 150. The chassis 160 is formed from an electrically non-conductive material. The chassis 160 electrically isolates components of the PCBA 150 from the second housing part 122.

The chassis 160 is between the PCBA 150 and the second housing part 122. An opening in the chassis provides access to the electronics module 150 from each side of the chassis 160. The PCBA 150 has a first surface 152 and a second surface 153. The first surface 152 is adjacent to the battery 174. The second surface is adjacent to the aerosol generator 102. The PCBA 150 and the chassis 160 bisect the body 104. In embodiments, the chassis is not present. The PCBA 150 may be attached to other components within the electronics assembly 170.

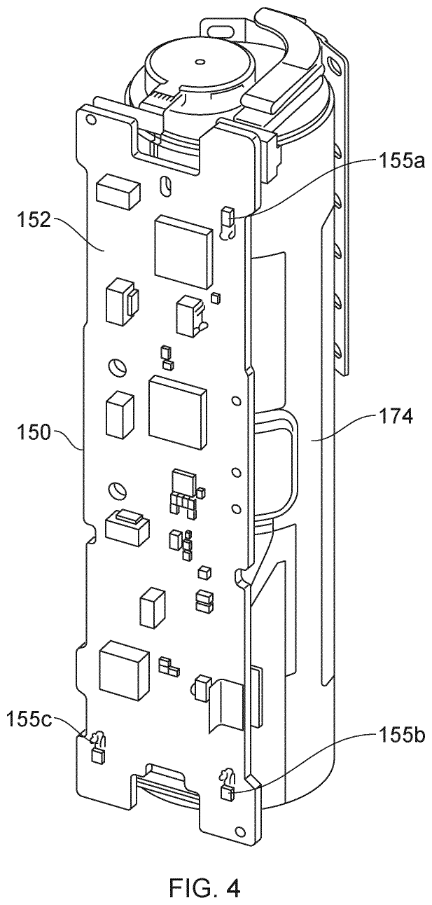

The PCBA 150 comprises an electrostatic discharge pathway arrangement 154. The electrostatic discharge pathway arrangement 154 provides a discharge path from the PCBA 150 to the first housing part 121. The electrostatic discharge pathway arrangement 154 comprises contact members 155. In embodiments, the PCBA may comprise a single contact member. In embodiments, the number of contact members differs and may be a single contact member. The present arrangement comprises three contact members 155a, 155b, 155c as shown in FIG. 4

FIG. 4 shows the battery 174 and the PCBA 150. The chassis is omitted in FIG. 4. The PCBA 150 is in electrical contact with the battery 174. FIG. 4 shows three contact members 155a, 155b, 155c. The contact members 155a, 155b, 155c are fixedly mounted on the PCBA 150. The contact members 155 are integrally formed with the PCBA 150. The contact members 155 protrude from one side of the PCBA 150. The contact members 155 are disposed on a first surface 152 of the PCBA 150. The contact members 155 extend from the PCBA 150 away from the first surface 152. The contact members extend from the PCBA 150 towards the first housing part 121. The contact members 155 protrude from a first surface 152 of the PCBA 150.

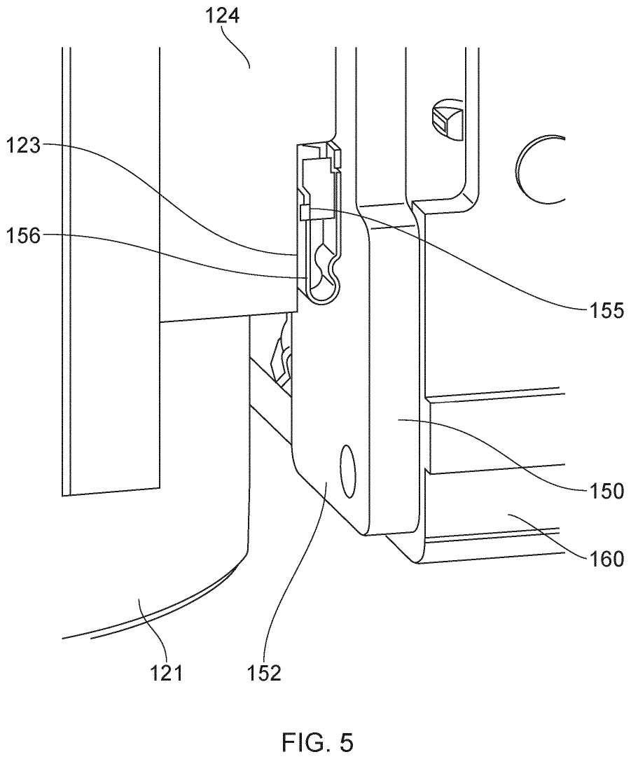

FIG. 5 shows the interaction of the contact members 155 with the first housing part 121. The contact members 155 are in electrical contact with the first housing part 121. The contact members 155 provide an electrostatic discharge pathway from the first housing part 121 to electrical discharge tracks on the PCBA 150. The first housing part 121 is electrically conductive.

Each contact member 155 comprises a resiliently deformable member. The contact members 155 is a spring element. The contact members 155 may be a sprung pin. The contact members 155 may comprise a flat spring. In embodiments, the contact members may not be resiliently deformable or sprung. The contact members may be static and fixed. In embodiments, the contact members 155 may be at least one of spring contacts, pogo pins, spring-loaded connectors, or conductive plates.

The contact members 155 are biased against the first housing part 121. The contact members 155 comprise a contact surface 156. The first housing part 121 comprises a connecting arrangement 124. The connection arrangement 124 connects the first housing part 121 with the chassis 160. Connectors (not shown) are arranged to mount the first housing part 121 with the chassis 160.

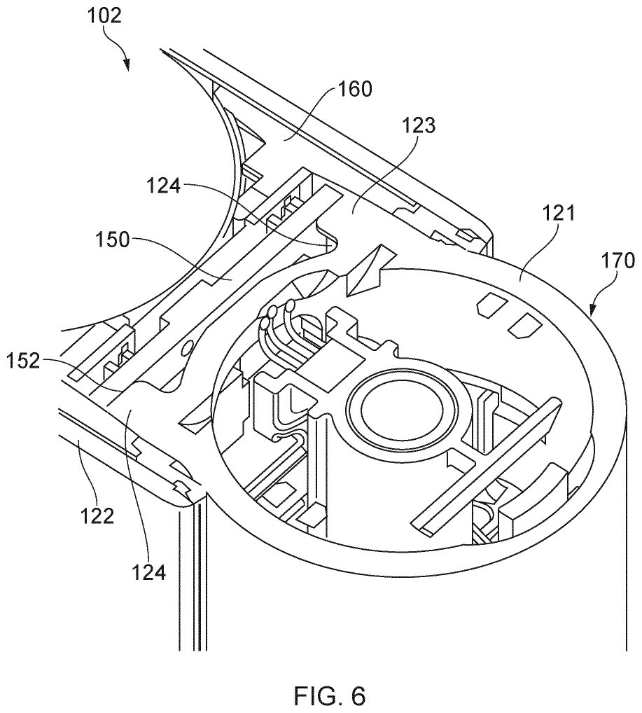

FIG. 6 shows the connection arrangement 124 and its interaction with the first housing part 121, chassis 160 and second housing part 122. The first housing part 121 is generally tubular. The first housing part 121 is open along one side to allow electrical connection between the heating assembly 140 and the electronics assembly 170.

The connecting arrangement 124 comprises protruding portions. The protruding portions are disposed on either side of the open side of the first housing part 121. The protruding portions protrude from the first housing part 121 towards the chassis 160 and PCBA 150. The connecting arrangement 124 extend axially parallel with the axis of the heating assembly 140. The connecting arrangement 124 is attached to the chassis 160 to hold the first housing part 121 in position relative to the second housing part 122. In embodiments, the first housing part 121 and second housing part 122 are connected to each other.

The connecting arrangement 124 is fixed in position relative to the PCBA 150 such that it is held in close proximity to the PCBA 150. The connecting arrangement 124 comprises a connecting contact surface 123. The contact surface 156 of the contact member 155 and the connecting contact surface 123 are in electrical contact.

The contact surface 156 is biased away from the PCBA 150 towards the first housing part 121. The contact members 155 are biased towards the connecting contact surface 123 of the first housing part 121 to provide continuous contact between the surfaces 156, 123 to provide a constant electrical pathway irrespective of differing tolerances and/or movement between respective components. By providing such an arrangement ease of assembly is maximised.

Each contact member 155 has a corresponding connecting contact surface 123 on the first housing part 121. The connecting arrangement 124 may have one or more connecting contact surface 123. The connecting contact surfaces 123 are at a distance away from the first surface 152 of the PCBA 150. The space between the connecting contact surfaces 123 and the first surface 152 of the PCBA 150 ensures that any electrostatic charge flows only through the contact members 155. The connecting contact surfaces 123 may be recessed from the connecting arrangement 124 of the first housing part 121 that protrudes towards the first surface 152 of the PCBA. The connecting arrangement 124 does not contact and is spaced from the first surface 152 of the PCBA. The depth of the recess is less than depth by which the contact member protrudes.

The contact members 155 are connected to a ground point of the device 100. The ground point may comprise a ground component. The connection between the first housing part 121, the contact members 155 and the ground component (not shown) allows electrostatic discharge to flow from the first housing part 121 to a ground point without affecting other components on the PCBA 150. The ground point may be within the body 104 of the device 100. The contact members 155 are electrically isolated from other components on the PCBA 150 such as to prevent electrostatic discharge from flowing through the PCBA 150 and causing damage to the PCB or its components. The electrostatic discharge path comprises a grounding path. The grounding path provides a path for electrostatic discharge to flow from the first housing part 121 through the chassis 160 and to the contact members 155 of PCBA 150. The first housing part 121 is connected to the chassis 160 by fixing points (not shown). The chassis 160 is in contact with the PCBA 150 by means of the contact members 155a, 155b, 155c on the PCBA 150. The contact members 155a, 155b, 155c are in embodiments soldered to points on the PCBA 150 which are connected to the ground point. The grounding path is the same for all of the contact members. The ground point is at zero volts. Other methods of attaching the contact members to the PCBA 150 may be used.

The first housing part 121 may be painted or anodised. The contact surface 124 is untreated so as to provide an uninterrupted electrically conductive pathway between the first housing part 121 and the ground point. The first housing part 121 may comprise a tubular member. The tubular member may receive the heating assembly 140. The tubular member may comprise holes in a sidewall of the tubular member to allow electrical connection between the heating assembly 140 and the electronics assembly 170. The first housing part 121 may comprise aluminum.

In use, any static build-up on the first housing part 121 flows through the contact surfaces to the contact members 155 and to the ground point. This diverts the electrostatic charge away from sensitive components on the PCBA 150. Electrical components or elements of the PCBA 150 are electrically isolated from the conductive first housing part 121. The flexible contact members 155 allow for larger tolerances in manufacture of the first housing part 121.

The device 100 is assembled by attaching the PCBA 150 to the chassis 160 forming the second sub-assembly. The aerosol generator 102 including the heating assembly 140 and the first housing part 121 are assembled as the first sub-assembly. The first sub-assembly including the first housing part 121 is then assembled with the second sub-assembly including the chassis 160 and PCBA 150. the contact members 155 are brought into abutment with the first housing part 121 as part of the assembly. The connecting contact surfaces 124 are brought into contact with the contact surfaces 156 of the contact members. The contact members 155 distend and are biased against the first housing part 121. The heating assembly 140 is electrically connected to the PCBA 150. A battery module sub-assembly comprising he battery 174 and thermal distribution assembly 172 is assembled with the PCBA 150 and chassis 160. The second housing part 122 is assembled the electronics assembly 170 such as to surround a portion of the chassis 160.

The various embodiments described herein are presented only to assist in understanding and teaching the claimed features. These embodiments are provided as a representative sample of embodiments only, and are not exhaustive and/or exclusive. It is to be understood that advantages, embodiments, examples, functions, features, structures, and/or other aspects described herein are not to be considered limitations on the scope of the invention as defined by the claims or limitations on equivalents to the claims, and that other embodiments may be utilized and modifications may be made without departing from the scope of the claimed invention. Various embodiments of the invention may suitably comprise, consist of, or consist essentially of, appropriate combinations of the disclosed elements, components, features, parts, steps, means, etc, other than those specifically described herein. In addition, this disclosure may include other inventions not presently claimed, but which may be claimed in future.

1. An aerosol provision device for generating aerosol from an aerosol-generating material, the device comprising:
a heating assembly;
an electrically conductive housing part arranged to at least partially receive the heating assembly;
an electronics module; and
a contact member;
wherein the at least one contact member is in electrical contact between the housing part and the electronics module to provide an electrostatic discharge pathway.

2. The aerosol provision device of claim 1, wherein the contact member extends from the electronics module.

3. The aerosol provision device of claim 1, wherein the contact member is fixedly mounted on the electronics module.

4. The aerosol provision device of claim 1, wherein the contact member is a resiliently deformable member.

5. The aerosol provision device of claim 1, wherein a contact surface of the contact member is biased away from the electronics module.

6. The aerosol provision device of claim 1, wherein the contact member is a spring element.

7. The aerosol provision device of claim 6, wherein the contact member comprises a sprung pin.

8. The aerosol provision device of claim 1, wherein the electronics module comprises a printed circuit board assembly (PCBA).

9. The aerosol provision device of claim 8, wherein the contact member protrudes from the PCBA.

10. The aerosol provision device of claim any of claim 1, wherein the contact member is biased against the housing part.

11. The aerosol provision device of claim any of claim 1, wherein the housing part comprises a connecting arrangement, and the contact member is in contact with the connecting arrangement.

12. The aerosol provision device of claim any of claim 1, wherein the device comprises a chassis.

13. The aerosol provision device of claim 1, wherein the electronics module is between the chassis and the heating assembly.

14. The aerosol provision device of claim 1, wherein the electronics module is mounted on the chassis.

15. The aerosol provision device of claim 1, wherein the contact member is one of a plurality of contact members.

16. The aerosol provision device of claim 1, wherein the at least one contact member is electrically connected to a ground point in the device.

17. The aerosol provision device of claim 1, wherein the at least one contact member is electrically isolated from other electrical elements of the electronics module.

18. The aerosol provision device of claim 1, wherein the electrically conductive housing part surrounds the heating assembly.

19. An aerosol provision system comprising an aerosol provision device of claim 1, and an article containing aerosol generating material arranged to be at least partially received by the aerosol provision device.

20. A method of assembling an aerosol provision device for generating an aerosol from aerosol-generating material, comprising:
providing an electronics module with an electrostatic discharge contact member,
bringing an electrically conductive housing part together with the electronics module so that the electrostatic discharge contact member is brought into contact with the electrically conductive housing part and provides an electrostatic discharge pathway between the housing part and electronics module.
